(19) United States
(12) Patent Application Publication
(10) Pub. No.: US 2024/0348028 A1
(43) Pub. Date: Oct. 17, 2024

(54) Electrical Junction Box Device

(71) Applicant: Nathan Seibert, Leitchfield, KY (US)

(72) Inventor: Nathan Seibert, Leitchfield, KY (US)

(21) Appl. No.: 18/495,171

(22) Filed: Oct. 26, 2023

Related U.S. Application Data
(60) Provisional application No. 63/495,651, filed on Apr. 12, 2023.

(51) Int. Cl. H02G 3/08; H02G 3/14; H05K 5/02

(52) U.S. Cl. CPC H02G 3/081; H02G 3/14; H05K 5/0247

(57) ABSTRACT

An electrical junction box device is disclosed that has a mounting support, as well as a cover which may fully enclose an open air splice. Specifically, the electrical junction box device comprises a body component that is configured in a rectangular shape that is simply slid behind and over the open air splice, then the cover component is installed over the body component to completely enclose the open air splice. The cover component is secured with four screws. Further, the body component comprises two holes, one at either end, to support the device on the nearest structure, as needed.

### CROSS-REFERENCE TO RELATED APPLICATION

The present application claims priority to, and the benefit of, U.S. Provisional Application No. 63/495,651, which was filed on Apr. 12, 2023, and is incorporated herein by reference in its entirety.

### FIELD OF THE INVENTION

The present invention relates generally to the field of electrical junction box devices. More specifically, the present invention relates to an improved junction box for covering open air electrical junctions in homes, attics, garages, etc. Accordingly, the present disclosure makes specific reference thereto. Nonetheless, it is to be appreciated that aspects of the present invention are also equally applicable to other like applications, devices and methods of manufacture.

### BACKGROUND

By way of background, this invention relates to improvements in electrical junction box devices. Generally, electrical junctions that are not in boxes are susceptible to damage and can create a severe hazard in homes, businesses, etc. For example, unsafe conditions, such as arc flashes, shock hazards, and electrical fires can occur if the junction is not safely confined in a box.

Furthermore, a common problem, especially in older homes, are electrical connections made without being housed in a junction box per typical code requirements. These connections are commonly referred to as “open splices.” Generally, a user must disconnect the power to the splice, disassemble the splice, and wire the connection up properly within a junction box with a lid or a user can install an open splice junction box. These open splice junction boxes are made of steel, require multiple screws and parts, and are expensive and time consuming to install. What is needed is an inexpensive, easy to use open splice box.

Accordingly, there is a demand for an improved, inexpensive, easy to use open splice box that covers open air splices by allowing users to slide the box over the open air splice and install the cover. More particularly, there is a demand for an electrical junction box that utilizes nonmetallic and nonconductive materials like plastic or fiberglass to reduce shock and fire hazards when installing the device.

Therefore, there exists a long felt need in the art for an electrical junction box device that provides users with an improved junction box for covering open air electrical junctions in homes, attics, garages, etc. There is also a long felt need in the art for an electrical junction box device that utilizes nonmetallic and nonconductive materials like plastic or fiberglass to reduce shock and fire hazards when installing the cover. Further, there is a long felt need in the art for an electrical junction box device that allows users to slide the box over the open air splice and install the cover with four screws. Moreover, there is a long felt need in the art for a device that saves considerable time and effort for electricians installing covers and boxes over electrical junctions. Further, there is a long felt need in the art for an electrical junction box device that also comprises two holes on the outside to support the device to the nearest structure. Finally, there is a long felt need in the art for an electrical junction box device that fully encloses an open air splice.

The subject matter disclosed and claimed herein, in one embodiment thereof, comprises an electrical junction box device. The device is a modified, nonconductive, and nonmetallic junction box comprised of a fiberglass or plastic material that has a mounting support, as well as a cover which may fully enclose the open air splice. Specifically, the electrical junction box device comprises a body component that is configured in a rectangular shape that is simply slid behind and over the open air splice, then the cover component is installed over the body component to completely enclose the open air splice. The cover component is secured with four screws. Further, the body component comprises two holes, one at either end, to support the device on the nearest structure, as needed. Thus, the cover component is removed before the body component is wrapped around the open air splice. Then, the cover component is placed back on and secured to fully enclose the open air splice.

In this manner, the electrical junction box device of the present invention accomplishes all of the forgoing objectives and provides users with a device that covers open air splices safely and easily. The device is a nonmetallic and nonconductive plastic structure that slides over an open air splice. The device can be manufactured of a plastic or fiberglass material.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises an electrical junction box device. The device has a mounting support, as well as a cover which may fully enclose an open air splice. Specifically, the electrical junction box device comprises a body component that is configured in a rectangular shape that is simply slid behind and over the open air splice, then the cover component is installed over the body component and secured to completely enclose the open air splice.

In one embodiment, the electrical junction box device comprises a one-piece electrical box, which is entirely molded and formed from a single piece of material. The electrical box has a body component and a removable cover component.

In one embodiment, the body component is typically configured in a rectangular shape, but can be any suitable size and shape as is known in the art, such as square, oval, circular, etc. Further, the body component comprises a bottom closed end, front and back opposing walls, right and left opposing walls, and an open top end. The body component forms an open cavity, accessed through the open top end. Generally, the body component is typically four or five inches square and two inches deep, or in another embodiment the body component is four by five inches rectangular and two inches deep, although not limited to such dimensions.

Further, the body component comprises junction box apertures, which are preferably generally opposite one another, located on the front and back opposing walls. The junction box apertures are approximately one-half inch in length and are shaped in a semi-circular or other suitable shape and extend into the body component. The junction box apertures are typically 0.1875 inch in width in the four-inch body component, so as to accept “12” and “14” gauge wire. In one embodiment, the junction box apertures of a five-inch body component is 0.250 inch, so as to accept up to “8” gauge wire.

Furthermore, in one embodiment, the body component also comprises punch-out inserts of varying length and width, which form additional apertures, which when removed, are used for feeding in additional wires of additional gauges, as needed, depending on the wants and/or needs of a user. Further, the punch-out inserts can be reinforced holes that are punched out within the walls to allow for additional wires to be drawn into the device. These, like the junction box apertures allow the device to be customized to have one or more openings to be opened allowing access to wires to be joined within the device. The punch-out inserts would have a thin layer of material which is pierceable by a user, a screw, a nail, etc. This material would be the same material that the rest of the device is formed from.

In one embodiment, a portion of the exposed wires is carefully placed through the junction box apertures, so that all of the wires are approximately centered within and reside, in part, within the body component. The existing wires are now secure within the body component and protected.

In one embodiment, the body component comprises approximately two holes, one at either end, near the front and back opposing walls, to support the device on the nearest structure, as needed. In one embodiment, the body component comprises a lip or protrusion at the front and back opposing ends, which allows for the mounting through-holes. The lip or protrusion extends away from body component approximately one inch or so, to allow the through-hole and mounting screw to be secured. For example, screws can be inserted into the two holes, allowing the electrical junction box device to be securely fixed to an adjacent beam, joist or the like, etc.

In one embodiment, the body component comprises a removable cover component which secures to the body component, to fully encapsulate the open air splice. The cover component attaches to the open top end of the body component. The cover component is typically configured in a rectangular shape but can be any suitable size and shape as is known in the art, such as square, oval, circular, etc., as long as the cover component matches the body component and is in the same configuration. Further, the cover component comprises a top closed end, front and back opposing walls, right and left opposing walls, and an open bottom end. The cover component forms an open cavity, accessed through the open bottom end. Generally, the cover component is typically four or five inches square and two inches deep, or in another embodiment the cover component is four by five inches rectangular and two inches deep, although not limited to such dimensions. Generally, the cover component mirrors the body component in shape and size, so as to encapsulate and protect the open air splice when the cover component is positioned on top of the body component and secured.

In one embodiment, the cover component comprises a living hinge which mates with the body component, all formed from the same material as the cover component and the body component. The living hinge allows the cover component to be easily opened and closed during use. Specifically, the cover component is easy to open about the living hinge and securely clasps shut against the body component via lid clasps.

Further, the cover component comprises junction box apertures, which are preferably generally opposite one another, located on the front and back opposing walls. The junction box apertures are approximately one-half inch in length and are shaped in a semi-circular, rectangular, or square shape and extend into the cover component. The junction box apertures mate with the junction box apertures of the body component, to form a circular or other suitable shape for retaining the wires from the open air splice. Specifically, the junction box apertures are typically 0.1875 inch in width in the four-inch cover component, so as to accept “12” and “14” gauge wire. In one embodiment, the junction box apertures of a five-inch cover component is 0.250 inch, so as to accept up to “8” gauge wire.

Furthermore, in one embodiment, the cover component also comprises punch-out inserts of varying length and width, which form additional apertures, which when removed, are used for feeding in additional wires of additional gauges, as needed, depending on the wants and/or needs of a user. The punch-out inserts are also lined up with the punch-out inserts of the body component, to form circular through-holes for additional wires. Further, the punch-out inserts can be reinforced holes that are punched out within the walls to allow for additional wires to be drawn into the device. These, like the junction box apertures allow the device to be customized to have one or more openings to be opened allowing access to wires to be joined within the device. The punch-out inserts would have a thin layer of material which is pierceable by a user, a screw, a nail, etc. This material would be the same material that the rest of the device is formed from.

In one embodiment, a portion of the exposed wires is carefully placed through the junction box apertures of the cover component, so that all of the wires are approximately centered within and reside, in part, within the body component and are fully encapsulated by the cover component. The existing wires are now secure within the body component and cover component and protected from shock and fire hazards.

In one embodiment, the cover component does not comprise a hinge but is secured via screws. Specifically, the cover component comprises approximately four holes, one at either corner of the top closed end, to secure the cover component to the body component during use. In one embodiment, the cover component comprises four through-holes, which accept mounting screws. For example, screws can be inserted into the four holes, allowing the cover component to be secured to the body component, to fully encapsulate the open air splice.

In one embodiment, the body component and the cover component act to waterproof the open air splice, preventing water from entering the device. In one embodiment, the junction box apertures of the body component and the cover component comprise a rubber seal around the circumference of the circular hole. The rubber seals acts to fill any gaps or egresses/ingresses around the wires protruding from the apertures. Thus, the wires within the device do not contact water, and the device itself is waterproof. In another embodiment, the wires protruding from the apertures comprise rubber tape or other suitable material around their outside diameters, which acts to fill in the gaps or egresses/ingresses between the wires and the apertures. Thus, the apertures do not need to be multiple sizes to fit different gauge wire. Instead, one sized aperture can be used and additional rubber tape can be wrapped around the wires to enlarge their diameters and fill the apertures, waterproofing the device.

In one embodiment, if individual conductor wires are secured within the device instead of bundled wires, then a grommet can be utilized within the body component. The grommet would have multiple slots or partitions which would act to secure the individual wires. Thus, the grommet would secure the individual wires in such a position that they would be bundled together, preventing gaps between the wires, where water could enter the device.

As stated supra, the entire assembly of the device is manufactured from a single, one-piece injection molding process and requires no additional parts other than mounting nails or screws. Additionally, the electrical junction box device is made of a lightweight, nonmetallic, nonconductive, durable material such as plastic, fiberglass, or the like and manufactured through common extruding and molding processes. Specifically, the device can be manufactured from heat-sealable plastic or polymers, such as polypropylene or acrylonitrile-butadiene-styrene (ABS), or any other suitable material as is known in the art, such as but not limited to, acrylic, polycarbonate, polyethylene, polyethylene terephthalate, polyvinyl chloride, polystyrene, etc. Generally, the electrical junction box device is also manufactured from a material that is water resistant or waterproof, or the body component and the cover component comprise a coating that is water resistant or waterproof.

Accordingly, by utilizing the electrical junction box device of the present invention, the electrician saves time and money by not having to re-pull wires and locating them where the conduit or cable terminates. Additionally, possible fire, shock and short hazards are avoided as the electrical junction box devices provide a protective casing for the spliced wires.

In one embodiment, a bracket or other extending component can be secured to the body component, allowing the device to be mounted in place for support.

In yet another embodiment, the electrical junction box device comprises a plurality of indicia.

In yet another embodiment, a method of completely enclosing an open air splice is disclosed. The method includes the steps of providing an electrical junction box device comprising a body component and a cover component that secure together over an open air splice. The method also comprises removing the cover component from the device. Further, the method comprises sliding the body component behind and over an open air splice. The method comprises replacing the cover component onto the body component to fully enclose the open air splice. Further, the method comprises securing the cover component to the body component. Finally, the method comprises securing the device via screws within the body component to the nearest structure.

Numerous benefits and advantages of this invention will become apparent to those skilled in the art to which it pertains, upon reading and understanding the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a front perspective view of one embodiment of the electrical junction box device of the present invention in accordance with the disclosed architecture;

FIG. 2 illustrates a side perspective view of one embodiment of the electrical junction box device of the present invention showing how the body component and the cover component are secured together in accordance with the disclosed architecture;

FIG. 3 illustrates a perspective view of one embodiment of the electrical junction box device of the present invention showing how the open air splice is secured with the device in accordance with the disclosed architecture;

FIG. 4 illustrates a perspective view of one embodiment of the electrical junction box device of the present invention showing the device in use in accordance with the disclosed architecture;

FIG. 5 illustrates a perspective view of one embodiment of the electrical junction box device of the present invention showing the holes on the body component for securing the device to the nearest structure in accordance with the disclosed architecture; and

FIG. 6 illustrates a flowchart showing the method of completely enclosing an open air splice in accordance with the disclosed architecture.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there is a long felt need in the art for an electrical junction box device that provides users with an improved junction box for covering open air electrical junctions in homes, attics, garages, etc. There is also a long felt need in the art for an electrical junction box device that utilizes nonmetallic and nonconductive materials like plastic or fiberglass to reduce shock and fire hazards when installing the cover. Further, there is a long felt need in the art for an electrical junction box device that allows users to slide the box over the open air splice and install the cover with four screws. Moreover, there is a long felt need in the art for a device that saves considerable time and effort for electricians installing covers and boxes over electrical junctions. Further, there is a long felt need in the art for an electrical junction box device that also comprises two holes on the outside to support the device to the nearest structure. Finally, there is a long felt need in the art for an electrical junction box device that fully encloses an open air splice.

The present invention, in one exemplary embodiment, is a novel electrical junction box device. The device is a modified, nonconductive, and nonmetallic junction box comprised of a fiberglass or plastic material that has a mounting support, as well as a cover which may fully enclose an open air splice. Specifically, the electrical junction box device comprises a body component that is configured in a rectangular shape that is simply slid behind and over the open air splice, then the cover component is installed over the body component to completely enclose the open air splice. The cover component is secured with four screws. Further, the body component comprises two holes, one at either end, to support the device on the nearest structure, as needed. The present invention also includes a novel method of completely enclosing an open air splice. The method includes the steps of providing an electrical junction box device comprising a body component and a cover component that secure together over an open air splice. The method also comprises removing the cover component from the device. Further, the method comprises sliding the body component behind and over an open air splice. The method comprises replacing the cover component onto the body component to fully enclose the open air splice. Further, the method comprises securing the cover component to the body component. Finally, the method comprises securing the device via screws within the body component to the nearest structure.

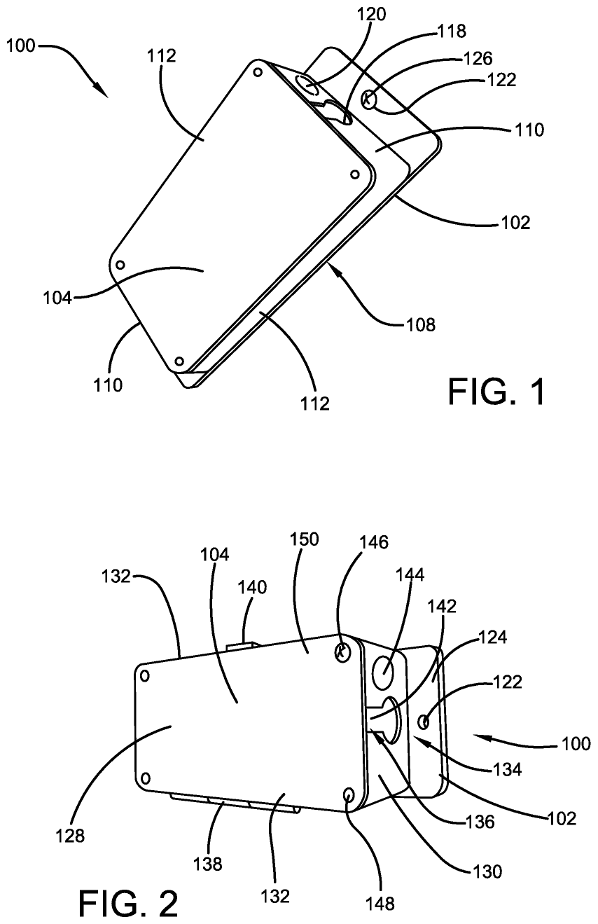

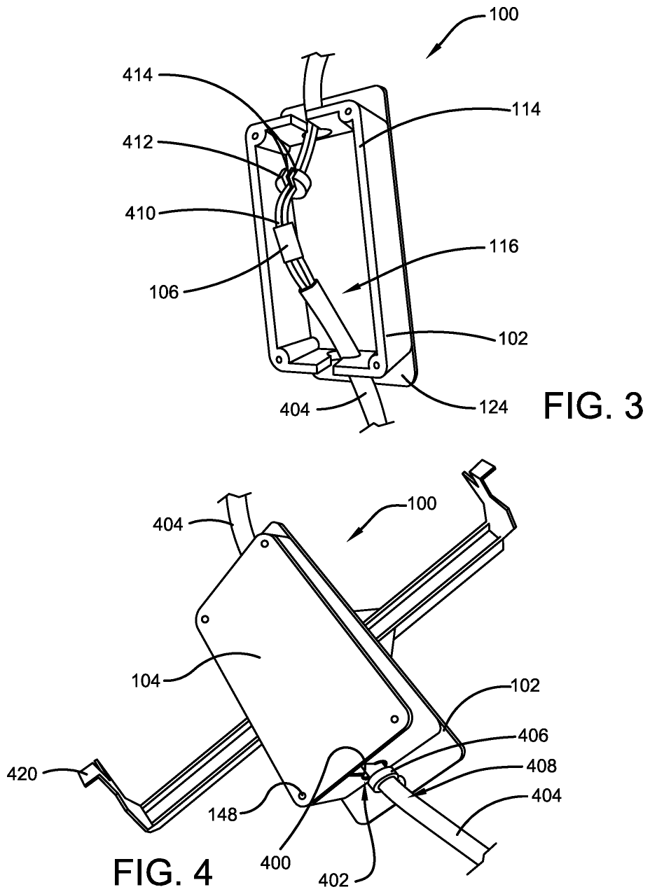

Referring initially to the drawings, FIGS. 1-3 illustrate a perspective view of one embodiment of the electrical junction box device 100 of the present invention. In the present embodiment, the electrical junction box device 100 is an improved electrical junction box device 100 that provides a user with a means for covering an open air splice 106 in homes, attics, garages, etc. Generally, the electrical junction box device 100 comprises a body component 102 with a cover component 104 that fits on top of the body component 102 to secure the open air splice 106 within. Specifically, the body component 102 is configured in a rectangular shape that is simply slid behind and over the open air splice 106, then the cover component 104 is installed over the body component 102 and secured to completely enclose the open air splice 106.

Generally, the electrical junction box device 100 comprises a one-piece electrical box, which is entirely molded and formed from a single piece of material. The electrical box has a body component 102 and a removable cover component 104. The removable cover component 104 allows access to the interior of the body component 102.

Furthermore, the body component 102 is typically configured in a rectangular shape, but can be any suitable size and shape as is known in the art, such as square, oval, circular, etc. Further, the body component 102 comprises a bottom closed end 108, front and back opposing walls 110, right and left opposing walls 112, and an open top end 114. The body component 102 forms an open cavity 116, accessed through the open top end 114. Generally, the body component 102 is typically four or five inches square and two inches deep, or in another embodiment the body component 102 is four by five inches rectangular and two inches deep, although not limited to such dimensions.

Additionally, the body component 102 comprises junction box apertures 118, which are preferably generally opposite one another, located on the front and back opposing walls 110. The junction box apertures 118 are approximately one-half inch in length and are shaped in a semi-circular or other suitable shape and extend through into the body component 102. The junction box apertures 118 are typically 0.1875 inch in width in the four-inch body component 102, so as to accept “12” and “14” gauge wire. In one embodiment, the junction box apertures 118 of a five-inch body component 102 is 0.250 inch, so as to accept up to “8” gauge wire. Thus, the junction box apertures 118 can be any suitable dimension to accept any suitable gauge wire.

Furthermore, in one embodiment, the body component 102 also comprises punch-out inserts 120 of varying length and width, which form additional apertures, which when removed, are used for feeding in additional wires of additional gauges, as needed, depending on the wants and/or needs of a user. Further, the punch-out inserts 120 can be reinforced holes that are punched out within the walls 110 to allow for additional wires to be drawn into the device 100. These, like the junction box apertures 118 allow the device 100 to be customized to have one or more openings to be opened allowing access to wires to be joined within the device 100. The punch-out inserts 120 would have a thin layer of material which is pierceable by a user, a screw, a nail, etc. This material would be the same material that the rest of the device 100 is formed from.

Generally, in use, a portion of the exposed wires is carefully placed through the junction box apertures 118, so that all of the wires are approximately centered within and reside, in part, within the body component 102. The existing wires (i.e., the open air splice 106) are now secure within the body component 102 and protected.

Further, the body component 102 comprises approximately two holes 122, one at either end, near the front and back opposing walls 110, to support the device 100 on the nearest structure, as needed. In one embodiment, the body component 102 comprises a lip or protrusion 124 at the front and back opposing walls 110, which allows for the mounting through-holes 122. The lip or protrusion 124 extends away from body component 102 approximately one inch or so, to allow the through-hole 122 and mounting screw 126 to be secured. For example, screws 126 can be inserted into the two holes 122, allowing the electrical junction box device 100 to be securely fixed to an adjacent beam, joist or the like, etc.

As stated supra, the body component 102 comprises a removable cover component 104 which secures to the body component 102, to fully encapsulate the open air splice 106. The cover component 104 attaches to the open top end 114 of the body component 102. The cover component 104 is typically configured in a rectangular shape but can be any suitable size and shape as is known in the art, such as square, oval, circular, etc., as long as the cover component 104 matches the body component 102 and is in the same configuration. Further, the cover component 104 comprises a top closed end 128, front and back opposing walls 130, right and left opposing walls 132, and an open bottom end 134. The cover component 104 forms an open cavity 136, accessed through the open bottom end 134. Generally, the cover component 104 is typically four or five inches square and two inches deep, or in another embodiment the cover component 104 is four by five inches rectangular and two inches deep, although not limited to such dimensions. Generally, the cover component 104 mirrors the body component 102 in shape and size, so as to encapsulate and protect the open air splice 106 when the cover component 104 is positioned on top of the body component 102 and secured.

In one embodiment, the cover component 104 comprises a living hinge 138 or any other suitable hinge, which mates with the body component 102, all formed from the same material as the cover component 104 and the body component 102. The living hinge 138 allows the cover component 104 to be easily opened and closed during use. Specifically, the cover component 104 is easy to open about the living hinge 138 and securely clasps shut against the body component 102 via lid clasps 140.

Further, the cover component 104 comprises junction box apertures 142, which are preferably generally opposite one another, located on the front and back opposing walls 130. The junction box apertures 142 are approximately one-half inch in length and are shaped in a semi-circular, rectangular, or square shape and extend through into the cover component 104. The junction box apertures 142 mate with the junction box apertures 118 of the body component 102, to form a circular or other suitable shape for retaining the wires from the open air splice 106. Specifically, the junction box apertures 142 are typically 0.1875 inch in width in the four-inch cover component 104, so as to accept “12” and “14” gauge wire. In one embodiment, the junction box apertures 142 of a five-inch cover component 104 is 0.250 inch, so as to accept up to “8” gauge wire.

Furthermore, in one embodiment, the cover component 104 also comprises punch-out inserts 144 of varying length and width, which form additional apertures, which when removed, are used for feeding in additional wires of additional gauges, as needed, depending on the wants and/or needs of a user. The punch-out inserts 144 are also lined up with the punch-out inserts 120 of the body component 102, to form circular through-holes for additional wires. Further, the punch-out inserts 144 can be reinforced holes that are punched out within the walls 130 to allow for additional wires to be drawn into the device 100. These, like the junction box apertures 142 allow the device 100 to be customized to have one or more openings to be opened allowing access to wires to be joined within the device 100. The punch-out inserts 144 would have a thin layer of material which is pierceable by a user, a screw, a nail, etc. This material would be the same material that the rest of the device 100 is formed from.

Generally, in use, a portion of the exposed wires is carefully placed through the junction box apertures 142 of the cover component 104, so that all of the wires are approximately centered within and reside, in part, within the body component 102 and are fully encapsulated by the cover component 104. The existing wires are now secure within the body component 102 and cover component 104 and protected from shock and fire hazards.

In one embodiment, the cover component 104 does not comprise a hinge 138 but is secured via screws 146. Specifically, the cover component 104 comprises approximately four holes 148, one at either corner 150 of the top closed end 128, to secure the cover component 104 to the body component 102 during use. In one embodiment, the cover component 104 comprises four through-holes 148, which accept mounting screws 146. For example, screws 146 can be inserted into the four holes 148, allowing the cover component 104 to be secured to the body component 102, to fully encapsulate the open air splice 106.

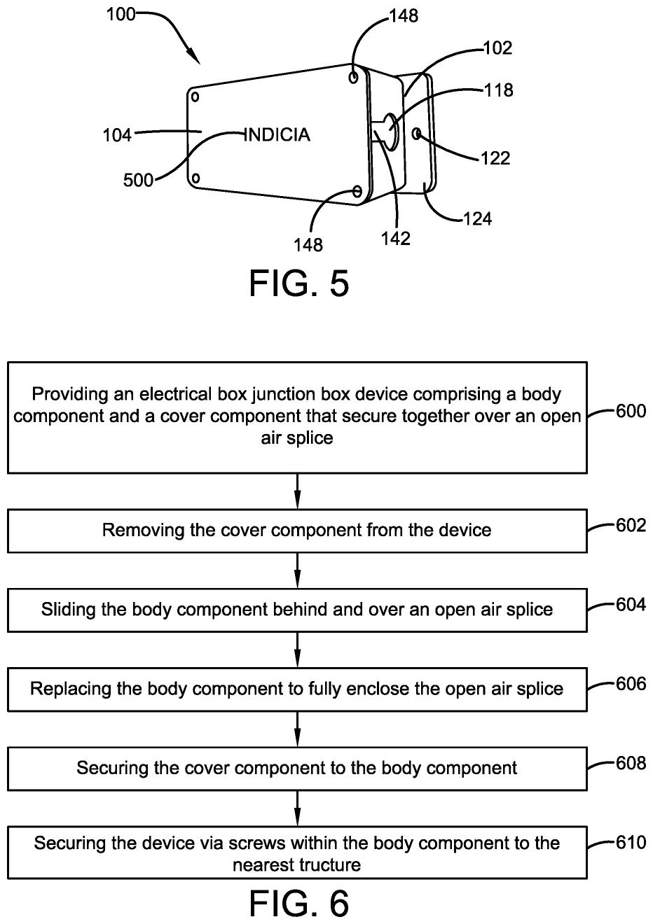

As shown in FIGS. 4-5, the body component 102 and the cover component 104 act to waterproof the open air splice 106, preventing water from entering the device 100. In one embodiment, the junction box apertures 118 and 142 of the body component 102 and the cover component 104 comprise a rubber seal 400 around the circumference 402 of the circular hole 118 and 142. The rubber seals 400 act to fill any gaps or egresses/ingresses around the wires 404 protruding from the apertures 118 and 142. Thus, the wires 404 within the device 100 do not contact water, and the device 100 itself is waterproof. In another embodiment, the wires 404 protruding from the apertures 118 and 142 comprise rubber tape 406 or other suitable material around their outside diameters 408, which acts to fill in the gaps or egresses/ingresses between the wires 404 and the apertures 118 and 142. Thus, the apertures 118 and 142 do not need to be multiple sizes to fit different gauge wire 404. Instead, one sized aperture 118 and 142 can be used and additional rubber tape 406 can be wrapped around the wires 404 to enlarge their diameters 408 and fill the apertures 118 and 142, waterproofing the device 100.

In one embodiment, if individual conductor wires 410 are secured within the device 100 instead of bundled wires 404, then a grommet 412 can be utilized within the body component 102. The grommet 412 would have multiple slots 414 or partitions which would act to secure the individual wires 410. Thus, the grommet 412 would secure the individual wires 410 in such a position that they would be bundled together, preventing gaps between the wires 410, where water could enter the device 100.

In one embodiment, a bracket 420 or other extending component can be secured to the body component 102, allowing the device 100 to be mounted in place for support. Specifically, the National Electric Code requires the device 100 to be supported, therefore the bracket 420 will extend to reach the nearest structure to support the device 100, up to 24 inches. Any suitable bracket 420 as is known in the art can be utilized to secure and support the device 100 in place.

As stated supra, the entire assembly of the device 100 is manufactured from a single, one-piece injection molding process and requires no additional parts other than mounting nails or screws 126 and 146. Additionally, the electrical junction box device 100 is made of a lightweight, nonmetallic, nonconductive, durable material such as plastic, fiberglass, or the like and manufactured through common extruding and molding processes. Specifically, the device 100 can be manufactured from heat-sealable plastic or polymers, such as polypropylene or acrylonitrile-butadiene-styrene (ABS), or any other suitable material as is known in the art, such as but not limited to, acrylic, polycarbonate, polyethylene, polyethylene terephthalate, polyvinyl chloride, polystyrene, etc. Generally, the electrical junction box device 100 is also manufactured from a material that is water resistant or waterproof, or the body component 102 and the cover component 104 comprise a coating that is water resistant or waterproof.

Accordingly, by utilizing the electrical junction box device 100 of the present invention, the electrician saves time and money by not having to re-pull wires and locating them where the conduit or cable terminates. Additionally, possible fire, shock and short hazards are avoided as the electrical junction box devices 100 provide a protective casing for the spliced wires.

In yet another embodiment, the electrical junction box device 100 comprises a plurality of indicia 500. The body component 102 and/or the cover component 104 of the device 100 may include advertising, a trademark, or other letters, designs, or characters, printed, painted, stamped, or integrated into the body component 102 and/or the cover component 104, or any other indicia 500 as is known in the art. Specifically, any suitable indicia 500 as is known in the art can be included, such as but not limited to, patterns, logos, emblems, images, symbols, designs, letters, words, characters, animals, advertisements, brands, etc., that may or may not be electrical, junction box, or brand related.

FIG. 6 illustrates a flowchart of the method of completely enclosing an open air splice. The method includes the steps of at 600, providing an electrical junction box device comprising a body component and a cover component that secure together over an open air splice. The method also comprises at 602, removing the cover component from the device. Further, the method comprises at 604, sliding the body component behind and over an open air splice. The method comprises at 606, replacing the cover component onto the body component to fully enclose the open air splice. Further, the method comprises at 608, securing the cover component to the body component. Finally, the method comprises at 610, securing the device via screws within the body component to the nearest structure.

Certain terms are used throughout the following description and claims to refer to particular features or components. As one skilled in the art will appreciate, different users may refer to the same feature or component by different names. This document does not intend to distinguish between components or features that differ in name but not structure or function. As used herein “electrical junction box device”, “junction box device”, “electrical device”, and “device” are interchangeable and refer to the electrical junction box device 100 of the present invention.

Notwithstanding the forgoing, the electrical junction box device 100 of the present invention can be of any suitable size and configuration as is known in the art without affecting the overall concept of the invention, provided that it accomplishes the above stated objectives. One of ordinary skill in the art will appreciate that the electrical junction box device 100 as shown in FIGS. 1-6 is for illustrative purposes only, and that many other sizes and shapes of the electrical junction box device 100 are well within the scope of the present disclosure. Although the dimensions of the electrical junction box device 100 are important design parameters for user convenience, the electrical junction box device 100 may be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An electrical junction box device that provides a user with a means for covering an open air splice, the electrical junction box device comprising:
a body component; and
a cover component;
wherein the body component is slid behind and over an open air splice;
wherein the cover component is secured on top of the body component to completely enclose the open air splice; and
further wherein the body component and the cover component act to protect the open air splice from shock and fire hazards.

2. The electrical junction box device of claim 1, wherein the body component is configured in a rectangular shape, comprising a bottom closed end, front and back opposing walls, right and left opposing walls, an open top end, and an open cavity accessed through the open top end.

3. The electrical junction box device of claim 2, wherein the body component comprises junction box apertures located on the front and back opposing walls, which accept wire.

4. The electrical junction box device of claim 3, wherein the body component also comprises punch-out inserts of varying length and width for accepting additional wires.

5. The electrical junction box device of claim 4, wherein the body component comprises a lip at either end, near the front and back opposing walls, wherein the lip comprises two holes, one at either end, to support the electrical junction box device on a structure.

6. The electrical junction box device of claim 5, wherein the cover component attaches to the open top end of the body component.

7. The electrical junction box device of claim 6, wherein the cover component is configured in a rectangular shape, comprising a top closed end, front and back opposing walls, right and left opposing walls, an open bottom end, and an open cavity accessed through the open bottom end.

8. The electrical junction box component of claim 7, wherein the cover component comprises a living hinge.

9. The electrical junction box component of the claim 7, wherein the cover component comprises junction box apertures located on the front and back opposing walls, which accept wire.

10. The electrical junction box device of claim 9, wherein the body component also comprises punch-out inserts of varying length and width for accepting additional wires.

11. The electrical junction box device of claim 10, wherein the cover component comprises four holes, one at each corner of the top closed end for accepting screws, to secure the cover component to the body component during use.

12. The electrical junction box device of claim 11, wherein the junction box apertures of the body component and the cover component comprise a rubber seal around their circumference to fill any gaps around protruding wires.

13. The electrical junction box device of claim 11, wherein protruding wires comprise rubber tape, which acts to fill in gaps.

14. An electrical junction box device that provides a user with a means for covering an open air splice, the electrical junction box device comprising:
a body component configured in a rectangular shape, comprising a bottom closed end, front and back opposing walls, right and left opposing walls, an open top end, and an open cavity accessed through the open top end; and
a cover component configured in a rectangular shape, comprising a top closed end, front and back opposing walls, right and left opposing walls, an open bottom end, and an open cavity accessed through the open bottom end;
wherein the body component is slid behind and over an open air splice;
wherein the body component and the cover component comprise junction box apertures located on the front and back opposing walls, which accept wire;
wherein the cover component comprises four holes, one at each corner of the top closed end for accepting screws, to secure the cover component to the body component during use and completely enclose the open air splice;
wherein the body component comprises a lip at either end, near the front and back opposing walls, wherein the lip comprises two holes, one at either end, to support the electrical junction box device on a structure; and
further wherein the open air splice is placed through the junction box apertures of the cover component and the body component, so that the open air splice is centered within and resides, in part, within the body component and is fully encapsulated by the cover component and protected from shock and fire hazards.

15. The electrical junction box component of claim 14, wherein the cover component comprises a living hinge.

16. The electrical junction box device of claim 14, wherein the junction box apertures of the body component and the cover component comprise a rubber seal around their circumference to fill any gaps around protruding wires.

17. The electrical junction box device of claim 14, wherein protruding wires comprise rubber tape, which acts to fill in gaps.

18. The electrical junction box device of claim 14 further comprising a bracket to support and secured the electrical junction box device in place.

19. The electrical junction box device of claim 14, wherein the body component comprises a grommet for bundling individual conductor wires together.

20. A method of completely enclosing an open air splice, the method comprising the following steps:
providing an electrical junction box device comprising a body component and a cover component that secure together over an open air splice;
removing the cover component from the device;
sliding the body component behind and over an open air splice;
replacing the cover component onto the body component to fully enclose the open air splice;
securing the cover component to the body component; and
securing the device via screws within the body component to the nearest structure.
